(19) United States
(12) Patent Application Publication
(10) Pub. No.: US 2005/0148145 A1
(43) Pub. Date: Jul. 7, 2005

(54) Semiconductor memory cell with buried dopant bit lines and salicided polysilicon word lines isolated by an array of blocks

(75) Inventors: Herb H. Huang, Eden Prairie, MN (US); Haiting Li, Shanghai (CN); Wen Xu, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 10/773,522

(22) Filed: Feb. 6, 2004

(30) Foreign Application Priority Data
Dec. 30, 2003 (CN) 200310122970.0

(51) Int. Cl. H01L 31/119

(52) U.S. Cl. 438/295

(57) ABSTRACT

A method for manufacturing ROM memory devices. The method includes forming a trench isolation structure within a cell region of a semiconductor substrate. The cell region is an array region for ROM memory devices. The method includes forming a gate structure within the cell region and forming a sidewall spacer on the gate structure, which is configured to overlap a portion of the trench isolation structure within the cell region to separate a buried bit line region of the cell region from an adjacent cell region. The method applies a refractory metal layer overlying the gate structure including sidewall spacers and exposed portion of the trench isolation structure. A step of alloying the refractory metal layer to the gate structure and exposed portions of source/drain regions to form silicided regions overlying the gate structure and source/drain regions is included. The refractory metal layer is selectively removed from sidewall spacers and exposed portion of the trench isolation structure.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK.

NOT APPLICABLE

### BACKGROUND OF THE INVENTION

The present invention is directed integrated circuits and their processing for the manufacture of semiconductor devices. More particularly, the invention provides a method and device for manufacturing a memory device including a ROM memory device having novel interconnect and isolation structures, which can be embedded on other applications. But it would be recognized that the invention has a much broader range of applicability. For example, the invention can be applied to other memory devices, integrated circuits, and other devices.

Over the past decades, integrated circuits have evolved from a handful of interconnected devices fabricated on a single chip of silicon to millions of devices on the single chip. Performance and complexity are far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits. Certain semiconductor devices are now being fabricated with features less than a quarter of a micron across.

As merely an example, one type of integrated circuit device is a family called memory devices. Memory devices include read-only-memory (ROM), which happen to be one of the simplest designs. ROM devices store a discrete state of a cell as either a “1” or “O” state. ROM devices can only be read after being placed on a system or sub-system. ROM devices are often programmed in one of the two states during their manufacture. There are generally two different ways to program the ROM devices. Such ways include field oxidation programming and implant programming-i.e., mask implant ROM devices. Each of these ways physically allows one of the discrete states to be stored in the memory cell. The memory cell is often only one of a plurality of such cells, which are formed in an array pattern. As technology evolves, such ROM array pattern has become denser and denser to pack more and more cells on a given region of semiconductor material. Unfortunately, ROM cells using conventional designs cannot effectively shrink beyond a design rule of 0.35 micron. There are many isolation and conduction limitations. Other limitations exist with respect to the fabrication of such ROM devices.

Conventional high-density mask ROM devices employ various flat-cell array layouts. Such array includes a plurality of buried N-doped (BN+) or P-doped (PN+) parallel bit-lines into silicon and a plurality of polysilicon/oxide word-lines fabricated on a top surface of the silicon perpendicular to the bit-lines. The set of BN+ or BP+ strips and set of polysilicon world lines are often important elements of each individual MOS device unit corresponding to one memory cell. Such elements also serve as local electronic interconnections for the memory cells to their peripheral outlets. To reduce wafer production costs, polysilicon gate/word lines are manufactured at the same time with the polysilicon gates for CMOS devices used in the periphery portion of the mask ROM. Unfortunately, such high-density ROM devices also suffer from many drawbacks. Here, shorting may occur between adjacent bit-lines. Additionally, such conventional devices also have parasitic problems when scaling down to smaller and smaller design rules. These and other limitations are described throughout the present specification and more particularly below.

From the above, it is seen that an improved technique for processing semiconductor devices is desired.

### BRIEF SUMMARY OF THE INVENTION

According to the present invention, techniques including methods for the manufacture of semiconductor devices are provided. More particularly, the invention provides a method and device for manufacturing a memory device including a ROM memory device having novel interconnect and isolation structures, which can be embedded on other applications. But it would be recognized that the invention has a much broader range of applicability. For example, the invention can be applied to flat-cell memory array comprising a plurality of buried N-doped (BN+) or P-doped (BP+) parallel bit-lines onto a silicon substrate and a plurality of polysilicon/oxide word-lines fabricated on top of a surface of the silicon substrate perpendicular to the bit-lines, and other devices.

In a specific embodiment, the invention provides a method for manufacturing ROM memory devices. The method includes forming a trench isolation structure within a cell region of a semiconductor substrate. The cell region is an array region for ROM memory devices. The method includes forming a gate structure within the cell region and forming a sidewall spacer on the gate structure, which is configured to overlap a portion of the trench isolation structure within the cell region to separate a buried bit line region of the cell region from an adjacent cell region. The method applies a refractory metal layer overlying the gate structure including sidewall spacers and exposed portion of the trench isolation structure. A step of alloying the refractory metal layer to the gate structure and exposed portions of source/drain regions to form silicided regions overlying the gate structure and source/drain regions is included. The refractory metal layer is selectively removed from sidewall spacers and exposed portion of the trench isolation structure.

In an alternative specific embodiment, the invention provides a semiconductor integrated circuit memory device structure. The device includes a semiconductor substrate, which has a memory cell array region for ROM devices and a peripheral region. Each of the memory cells includes a trench isolation structure within the memory cell region, a gate structure within the memory cell region, and a source/drain region adjacent to the gate structure. A buried bit line region is coupled to the source/drain region. A sidewall spacer is on the gate structure. Preferably, the sidewall spacer structure is configured to overlap a portion of the trench isolation structure within the memory cell region to separate the buried bit line region of the memory cell region from an adjacent memory cell region and also is configured to overlap a portion of the source/drain region. A refractory metal layer is formed overlying a top portion of the gate structure and an exposed portion of the source/drain region while maintaining the sidewall spacer and exposed portion of the trench region structure free from the refractory metal layer.

Many benefits are achieved by way of the present invention over conventional techniques. For example, the present technique provides an easy to use process that relies upon conventional technology. In some embodiments, the method provides higher device yields in dies per wafer. Additionally, the method provides a process that is compatible with conventional process technology without substantial modifications to conventional equipment and processes. In some aspects, the invention provides a highly integrated ROM cell, which is more reliable and efficient. The present invention can be implemented with highly integrated devices such as ROM cells having a channel length of less than 0.35 microns. In a specific embodiment, the invention provides dielectric isolation or insulation to reduce potential parasitic effects and punch-through between adjacent bit lines, i.e., BN+ or BP+ bit lines in their open, non-channel area aside of perpendicular polysilicon word lines. Additionally, the invention can provide a self-aligned silicide (salicide) polysilicon gate metal contact formation on top of all the word-lines without shorting any two adjacent bit-lines to metallization. Preferably, the invention includes a method that facilitates a single step self-aligned metallization process simultaneously for both the flat-cell memory array and its periphery CMOS devices, or others, which are free from shorting between the buried N+ or P+ bit lines. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified top-view diagram of a ROM memory device in an array according to an embodiment of the present invention;

FIG. 2 is a simplified top-view diagram of a ROM memory device in an array according to an alternative embodiment of the present invention;

FIG. 3 is a simplified cross-sectional view diagram of a ROM cell array of FIG. 2 according to an embodiment of the present invention;

FIG. 4 is a simplified cross-sectional view diagram of a ROM cell array of FIG. 2 according to an alternative embodiment of the present invention;

FIGS. 5 is a simplified perspective view diagram of a ROM cell according to an alternative embodiment of the present invention

### DETAILED DESCRIPTION OF THE INVENTION

According to the present invention, techniques including methods for the manufacture of semiconductor devices are provided. More particularly, the invention provides a method and device for manufacturing a memory device including a ROM memory device having novel interconnect and isolation structures, which can be embedded on other applications. But it would be recognized that the invention has a much broader range of applicability. For example, the invention can be applied to flat-cell memory array comprising a plurality of buried N-doped (BN+) or P-doped (BP+) parallel bit-lines onto a silicon substrate and a plurality of polysilicon/oxide word-lines fabricated on top of a surface of the silicon substrate perpendicular to the bit-lines, and other devices.

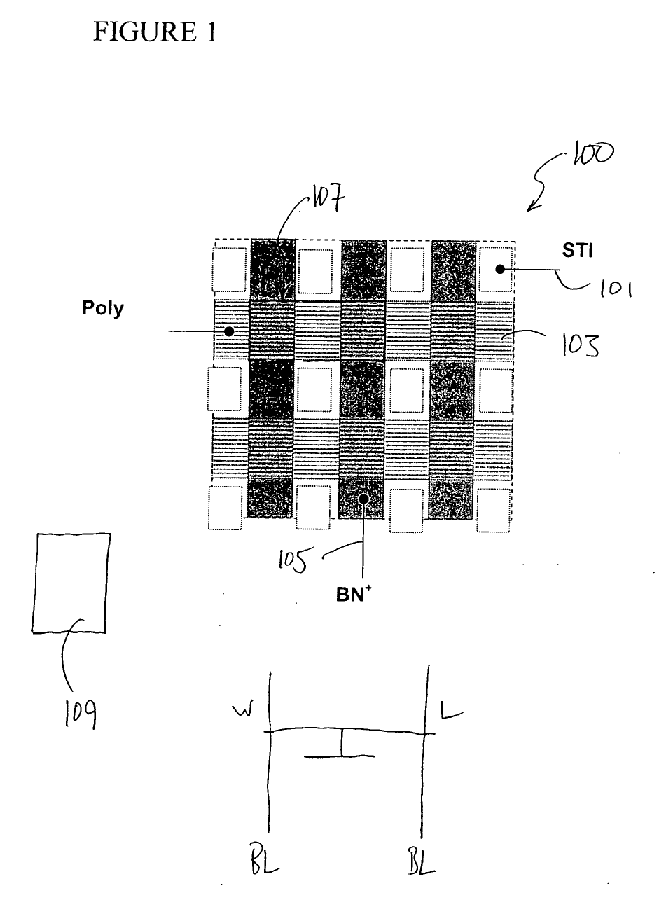

FIG. 1 is a simplified top-view diagram of a memory device 100 in an array according to an embodiment of the present invention. This diagram is merely an example, which should not unduly limit the scope of the claims herein. One of ordinary skill in the art would recognize many other variations, modifications, and alternatives. As shown, the top view diagram of the device is provided for a memory array region. The memory array region includes a plurality of memory cells. Each of the memory cells 107 includes a read only memory (“ROM”) device, but can also be others. A peripheral region 109 is also included. The peripheral region includes logic circuitry, input/output drivers, sense amplifiers, and other devices. The peripheral region can also include sub-system devices, such as processing devices, e.g., digital signal processing, microprocessor, and micro-controller devices. The array region includes a plurality of trench isolation regions 101, which separate each of the cells from each other. The array region also includes a plurality of polysilicon word lines 103, which run along a first direction in parallel to each other. The array region also includes a plurality of bit lines 105, which are buried regions. Each of the bit lines also couple to source/drain regions for each of the memory devices.

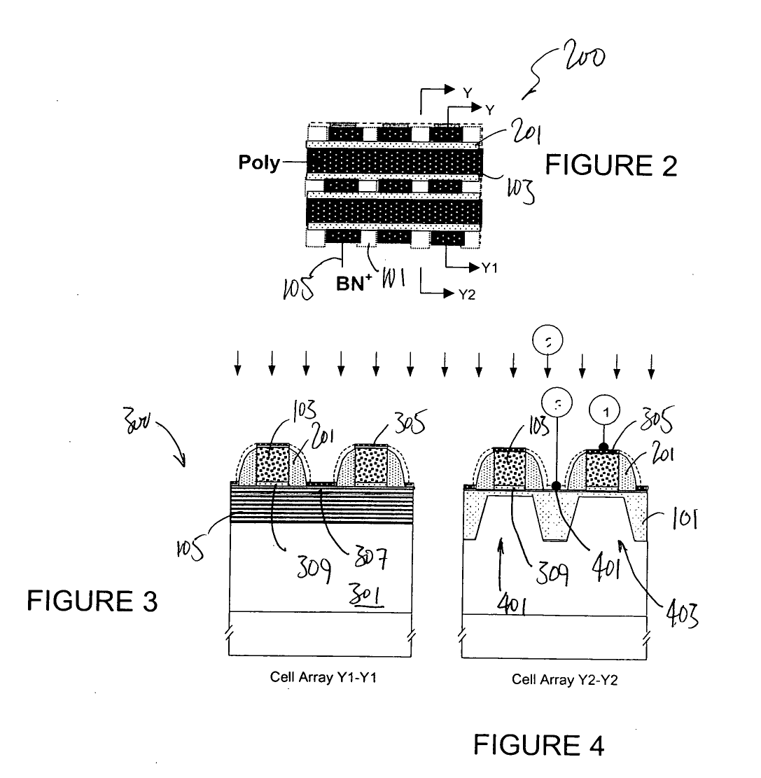

FIG. 2 is a simplified top-view diagram of a memory device 200 in an array according to an alternative embodiment of the present invention. This diagram is merely an example, which should not unduly limit the scope of the claims herein. One of ordinary skill in the art would recognize many other variations, modifications, and alternatives. Like reference numerals are used in FIG. 2 as some of the other Figures described herein. Such reference numerals are not intended to be limiting in any manner, but are provided for cross-referencing purposes only. As shown, the top view diagram of the device is provided for the memory array region. The memory array region includes the plurality of memory cells, which are isolated from each other. Each of the memory cells 107 includes the read only memory (“ROM”) device, but can also be others. As shown is the peripheral region 109. The peripheral region includes logic circuitry, input/output drivers, sense amplifiers, and other devices. The peripheral region can also include sub-system devices, such as processing devices, e.g., digital signal processing, microprocessor, micro-controller devices. The array region includes the plurality of trench isolation regions 101, which separate each of the cells from each other. The array region also includes the plurality of polysilicon word lines 103, which run along a first direction in parallel to each other. The array region also includes the plurality of bit lines 105, which are buried regions. Each of the bit lines also couple to source/drain regions for each of the memory devices. A sidewall spacer 201 is formed adjacent to the polysilicon word line. The top portion of the word line and top portion of the bit line include refractory metal, which reduces a resistance value of the word line and the bit line. The refractory metal layer can include a titanium silicide layer, a tungsten silicide layer, any combination of these, and others. Cross-sectional view diagrams of the array region are provided below, where cross-sections between Y and Y2 and Y and Y1 are shown.

FIG. 3 is a simplified cross-sectional view diagram of a cell array of FIG. 2 according to an embodiment of the present invention. This diagram is merely an example, which should not unduly limit the scope of the claims herein. One of ordinary skill in the art would recognize many other variations, modifications, and alternatives. Like reference numerals are used in FIG. 3 as some of the other Figures described herein. As shown, the cross-sectional view is between Y and Y1, which is across the bit line structure within substrate 301. The side-view diagram includes word line 103, which overlies dielectric layer 309. The dielectric layer is a gate dielectric layer. Such gate dielectric layer can include silicon dioxide, silicon nitride, any combination of these and the like. The buried bit line 105 is also included. Sidewall spacers 201 are formed using conventional processes adjacent to the word line structure. A refractory metal layer 305 is formed overlying the top of the word line. A refractory metal layer 307 is also formed overlying the exposed portion of the buried bit line, which also serves as source/drain region. The refractory metal overlying the buried bit line reduces a resistance value of the buried bit line. A further cross-section of the array structure is provided below.

FIG. 4 is a simplified cross-sectional view diagram of a cell array of FIG. 2 according to an alternative embodiment of the present invention. This diagram is merely an example, which should not unduly limit the scope of the claims herein. One of ordinary skill in the art would recognize many other variations, modifications, and alternatives. Like reference numerals are used in FIG. 4 as some of the other Figures described herein. As shown, the cross-sectional view is between Y and Y2, which are across the trench isolation structure. The side-view diagram includes word line 103, which overlies dielectric layer 309. The dielectric layer is a gate dielectric layer. Such gate dielectric layer can include silicon dioxide, silicon nitride, any combination of these and the like. The buried bit line 105 is also included. Sidewall spacers 201 are formed using conventional processes adjacent to the word line structure. The sidewall spacer includes a portion that is formed overlying a portion of the trench region. A refractory metal layer 305 is formed overlying the top of the word line. A top portion 401 of the trench region 101 is substantially free from any conductive layer such as the refractory metal layer. Accordingly, a first memory cell region 401 is isolated from a second memory cell region 403 by way of the trench isolation 101, which is provided between each of these cell regions. The trench isolation region is formed to a depth below the buried bit line region. Further details of the present invention are provided below.

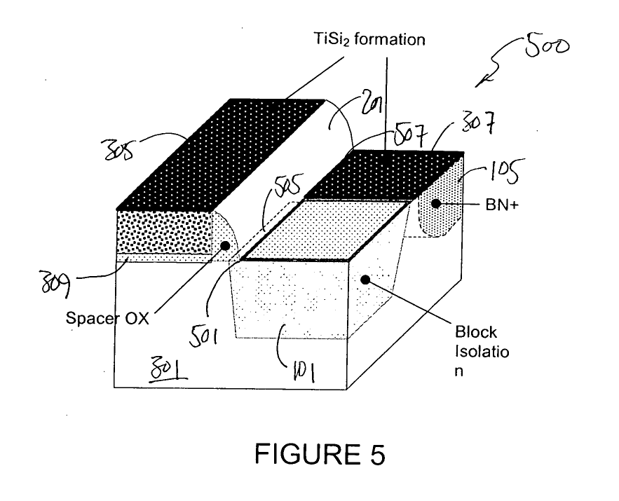

FIG. 5 is a simplified perspective view diagram 500 of a cell according to an alternative embodiment of the present invention. This diagram is merely an example, which should not unduly limit the scope of the claims herein. One of ordinary skill in the art would recognize many other variations, modifications, and alternatives. Like reference numerals are used in FIG. 5 as some of the other Figures described herein. As shown, the perspective view diagram illustrates the buried bit line and trench region in a single drawing. The side-view diagram includes word line 103, which overlies dielectric layer 309. The dielectric layer is a gate dielectric layer. Such gate dielectric layer can include silicon dioxide, silicon nitride, any combination of these and the like. The refractory metal layer 305 is formed overlying the top of the word line. The buried bit line 105 is also included. Sidewall spacers 201 are formed using conventional processes adjacent to and across a length of the word line structure. The sidewall spacer includes a portion 505 that is formed overlying a portion 501 of the trench region, which isolates the word line or cell from an adjacent cell. The spacer also includes a portion 507 adjacent to the buried bit line. A top portion 401 of the trench region 101 is substantially free from any conductive layer such as the refractory metal layer. The trench isolation region is formed to a depth below the buried bit line region. The refractory metal layer 307 forms overlying the source/drain region, which is also the buried bit line.

A method according to an embodiment of the present invention may be briefly outlined as follows:

1. Provide semiconductor substrate;

2. Define a ROM cell region within the substrate;

3. Form a trench isolation structure within the cell region of the semiconductor substrate;

4. Form a gate structure within the cell region;

5. Form a sidewall spacer on the gate structure, where the sidewall spacer structure overlaps a portion of the trench isolation structure within the cell region to separate a buried bit line region of the cell region from an adjacent cell region;

6. Apply a refractory metal layer overlying the gate structure including sidewall spacers and exposed portion of the trench isolation structure;

7. Alloy the refractory metal layer to the gate structure and exposed portions of source/drain regions to form silicided regions overlying the gate structure and source/drain regions; and

8. selectively remove the refractory metal layer from sidewall spacers and exposed portion of the trench isolation structure.

The above sequence of steps provides general steps, which have been illustrated in the above figures. These steps are used for form a self-aligned refractory metal layer for ROM integrated circuit devices. Depending upon the embodiment, there can be many variations, alternatives, and modifications.

A method according to an alternative embodiment of the present invention may be briefly outlined as follows:

1. Provide semiconductor substrate;

2. Define a ROM cell region and peripheral region within the substrate;

3. Form a trench isolation structure within the cell region of the semiconductor substrate;

4. Form a gate structure within the cell region and a gate structure within the peripheral region;

5. Form a sidewall spacer on the gate structures in the peripheral region and the cell region, where the sidewall spacer structure overlaps a portion of the trench isolation structure within the cell region to separate a buried bit line region of the cell region from an adjacent cell region;

6. Apply a refractory metal layer overlying the gate structures including sidewall spacers and exposed portion of the trench isolation structure in the cell and peripheral regions;

7. Alloy the refractory metal layer to the gate structure and exposed portions of source/drain regions to form silicided regions overlying the gate structure and source/drain regions;

8. Selectively remove the refractory metal layer from sidewall spacers and exposed portion of the trench isolation structure to pattern the refractory metal layer using a self-aligned process;

9. Apply isolation layer overlying the refractory metal layer and other structures; and

10. Perform other steps, as desired.

The above sequence of steps provides general steps, which have been illustrated in the above figures. These steps are used for form a self-aligned refractory metal layer for ROM integrated circuit devices and devices in the peripheral regions. Depending upon the embodiment, there can be many variations, alternatives, and modifications.

It is also understood that the examples and embodiments described herein are for illustrative purposes only and that various modifications or changes in light thereof will be suggested to persons skilled in the art and are to be included within the spirit and purview of this application and scope of the appended claims.

1. A method for manufacturing ROM memory devices, the method comprising:
forming a trench isolation structure within a cell region of a semiconductor substrate, the cell region being an array region for ROM memory devices;
forming a gate structure within the cell region;
forming a sidewall spacer on the gate structure, the sidewall spacer structure being configured to overlap a portion of the trench isolation structure within the cell region to separate a buried bit line region of the cell region from an adjacent cell region;
applying a refractory metal layer overlying the gate structure including sidewall spacers and exposed portion of the trench isolation structure;
alloying the refractory metal layer to the gate structure and exposed portions of source/drain regions to form silicided regions overlying the gate structure and source/drain regions; and
selectively removing the refractory metal layer from sidewall spacers and exposed portion of the trench isolation structure.

2. The method of claim 1 wherein the refractory metal layer is titanium or cobalt.

3. The method of claim 1 wherein the trench isolation region is an STI region.

4. The method of claim 3 wherein the STI region comprises silicon dioxide.

5. The method of claim 1 wherein the cell region has a channel region using a length of about 0.25 micron and less.

6. The method of claim 1 wherein the sidewall spacer is a dielectric material.

7. The method of claim 1 wherein the buried bit line structure is within the source/drain region.

8. The method of claim 1 wherein the trench isolation is within the semiconductor substrate at a predetermined depth, the predetermined depth being greater than a junction depth of the buried bit line.

9. The method of claim 1 wherein the gate structure has a width of 0.25 micron and less.

10. The method of claim 1 wherein the array has at least eight cells by eight cells.

11 A semiconductor integrated circuit memory device structure comprising:
a semiconductor substrate, the semiconductor substrate including a memory cell array region for ROM devices and a peripheral region; each of the memory cells including:
a trench isolation structure within the memory cell region;
a gate structure within the memory cell region;
a source/drain region adjacent to the gate structure;
a channel region adjacent to the source/drain region and underlying the gate structure;
a buried bit line region coupled to the source/drain region and the channel region;
a sidewall spacer on the gate structure, the sidewall spacer structure being configured to overlap a portion of the trench isolation structure within the memory cell region to separate the buried bit line region of the memory cell region from an adjacent memory cell region and being configured to overlap a portion of the source/drain region;
a refractory metal layer formed overlying a top portion of the gate structure and an exposed portion of the source/drain region while maintaining the sidewall spacer and exposed portion of the trench region structure free from the refractory metal layer.

12. The device of claim 11 wherein the buried bit line region is an implanted region.

13. The device of claim 11 wherein the peripheral region comprises one or more MOS transistor structures.

14. The device of claim 11 wherein the refractory metal layer is a titanium silicide layer.

15. The device of claim 11 wherein the channel region has a length of about 0.35 micron and less.

16. The device of claim 11 wherein the trench isolation structure is formed to a predetermined depth, the predetermined depth being greater than a junction depth of the buried bit line region.

17. The device of claim 11 wherein the exposed portion of the trench region and the sidewall spacer portion that overlaps the portion of the trench isolation region separates the buried bit line region of the memory cell from the adjacent memory cell region.

18. The device of claim 11 wherein the source/drain region is within the buried region.

19. The device of claim 11 wherein the gate structure is an MOS transistor gate structure.

20. A ROM semiconductor device comprising:
a plurality of alternatively arranged select lines and bit lines defined on a silicon substrate;
a plurality of word lines arranged substantially orthogonal to the select lines and the bit lines defined on the silicon substrate;
a plurality of isolation blocks defined in etched trench regions of the silicon substrate, each of the blocks being formed between a mutually orthogonal pair of word lines and bit lines or select lines to isolation the mutually orthogonal pair of word lines and isolate the bit lines or isolate the select lines.

21. The ROM device of claim 20 further comprising one or more MOS transistor structures on a peripheral region outside of the plurality of word lines, select lines, and bit lines.

22. The ROM device of claim 20 wherein the select lines and the bit lines are heavily doped regions in the silicon substrate.

23. The ROM device of claim 20 wherein each of the word lines comprise sidewall spacers defined on edges of the word lines, each of the sidewall spacers include a portion that overlaps a portion of a plurality of isolation blocks and overlaps a portion of bit lines.

24. The ROM device of claim 20 wherein the isolation blocks are formed in the silicon substrate to a predetermined depth, the predetermined depth being greater than a junction depth of the bit lines.

25. The ROM device of claim 20 further comprising a refractory metal layer formed overlying exposed portions of the bit lines and select lines and formed overlying exposed portions of the

26. The ROM device of claim 25 further comprising a pair of sidewall spacer structures defined on each of the word lines, the sidewall spacer structure being free from the refractory metal layer.
